(19) United States
(12) Patent Application Publication
(10) Pub. No.: US 2025/0338435 A1
(43) Pub. Date: Oct. 30, 2025

(54) COLD PLATE

(71) Applicant: NIDEC CORPORATION, Kyoto (JP)

(72) Inventors: Takaya OKUNO, Kyoto (JP); Takehito TAMAOKA, Kyoto (JP)

(21) Appl. No.: 19/188,342

(22) Filed: Apr. 24, 2025

Related U.S. Application Data
(60) Provisional application No. 63/638,510, filed on Apr. 25, 2024.

(30) Foreign Application Priority Data
Jul. 31, 2024 (JP) 2024-125248

(51) Int. Cl. H05K 7/20

(52) U.S. Cl. CPC H05K 7/20254; H05K 7/20272

(57) ABSTRACT

A cold plate includes a bottom wall, a top wall, blades, and a side wall. The bottom wall includes a lower surface in thermal contact with a heat generating component. The top wall covers an upper surface of the bottom wall. The blades are arranged side by side on the upper surface of the bottom wall. The side wall is located between the bottom wall and the top wall, and includes a refrigerant flow path that surrounds the blades and through which the refrigerant flows. The bottom wall includes column portions that protrude from the upper surface of the bottom wall, and oppose each other in the extending direction of the blades over the blades inside the side wall. The upper end of the column portion is located at the same position as the upper end of the blade or above the upper end of the blade.

### CROSS-REFERENCE TO RELATED APPLICATIONS

The present application is a non-provisional of U.S. Patent Application No. 63/638,510, filed on Apr. 25, 2024, and claims priority under 35 U.S.C. § 119 to Japanese Patent Application No. 2024-125248, filed on Jul. 31, 2024, the entire contents of which are each hereby incorporated herein by reference.

### 1. FIELD OF THE INVENTION

The present invention relates to cold plates.

### 2. BACKGROUND

A conventional cold plate includes a bottom wall, a top wall, a plurality of blades, and a side wall. The bottom wall has a lower surface to be in thermal contact with a heat generating component. The top wall covers an upper surface of the bottom wall. The blades are arranged side by side on the upper surface of the bottom wall and extend linearly. The side wall connects the bottom wall and the top wall, and forms a refrigerant flow path that surrounds the blades and through which refrigerant flows. The cold plate is manufactured by joining the bottom wall and the top wall.

However, in the conventional cold plate, there is a possibility that the blades are deformed and the cooling effect is lowered when the top wall is joined to the bottom wall.

### SUMMARY

An example embodiment of a cold plate of the present disclosure includes a bottom wall, a top wall, blades, and a side wall. The bottom wall includes a lower surface in thermal contact with a heat generating component. The top wall covers an upper surface of the bottom wall. The blades are arranged side by side on the upper surface of the bottom wall and extend linearly. The side wall is located between the bottom wall and the top wall, and defines a refrigerant flow path that surrounds the blades and through which the refrigerant flows. The bottom wall includes column portions that protrude from the upper surface of the bottom wall and oppose the extending direction of the blades with the blades interposed therebetween inside the side wall. The upper end of the column portions is located at the same position as the upper ends of the blades or above the upper ends of the blades.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a perspective view of a cold plate according to a first example embodiment of the present disclosure.

FIG. 2 is a front view of the cold plate according to the first example embodiment.

FIG. 3 is a cross-sectional view taken along line A-A in FIG. 2.

FIG. 4 is a cross-sectional view taken along line B-B in FIG. 2.

FIG. 5 is a top view of a bottom wall of the cold plate according to the first example embodiment of the present disclosure.

FIG. 6 is an enlarged perspective view illustrating a part of the cold plate according to the first example embodiment of the present disclosure.

FIG. 7 is a top view illustrating a modification of a bottom wall of the cold plate according to the first example embodiment of the present disclosure.

FIG. 8 is an exploded perspective view of a cold plate according to a second example embodiment of the present disclosure.

FIG. 9 is a perspective view of an intermediate lid of the cold plate according to the second example embodiment of the present disclosure.

FIG. 10 is a top view of the cold plate according to the second example embodiment of the present disclosure.

FIG. 11 is a cross-sectional view taken along line C-C in FIG. 10.

FIG. 12 is a cross-sectional view taken along line D-D in FIG. 10.

### DETAILED DESCRIPTION

Example embodiments of the present disclosure will be described below with reference to the drawings. In the present application, the facing direction of a bottom wall 12 and a top wall 13 is referred to as a “vertical direction”. In addition, a direction in which the top wall 13 is located with respect to the bottom wall 12 is referred to as “upward”, and a direction opposite to the direction in which the top wall 13 is located is referred to as “downward”. Moreover, in the present application, a direction orthogonal to the “vertical direction” is referred to as a “horizontal direction”, and the shape and positional relationships of the respective parts will be described.

A direction in which a blade 12a of a cold plate 10 extends is defined as an extending direction (X1-X2), and a direction in which the blades 12a are arranged is defined as an arranging direction (Y1-Y2). In the present example embodiment, the vertical direction (Z1-Z2) is orthogonal to the extending direction (X1-X2) and the arrangement direction (Y1-Y2). However, the vertical direction and the horizontal direction are defined merely for convenience of description, and the orientations of the cold plate 10 according to the present disclosure at the time of manufacture and at the time of use are not limited.

In addition, a “parallel direction” in the present application includes a substantially parallel direction. Moreover, an “orthogonal direction” in the present application includes a substantially orthogonal direction.

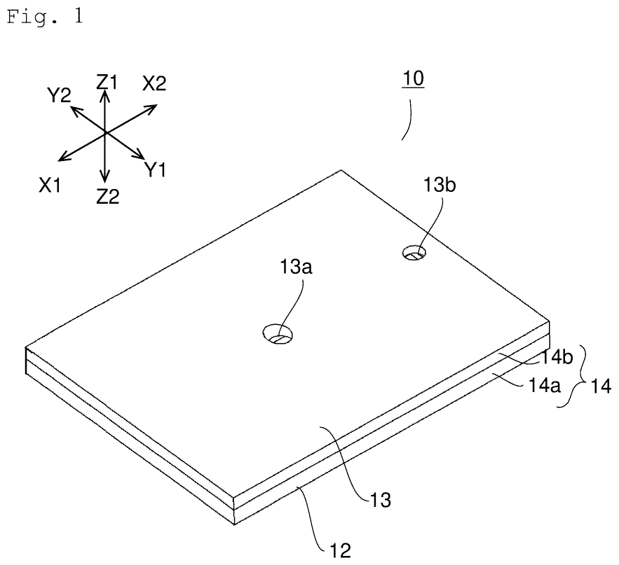

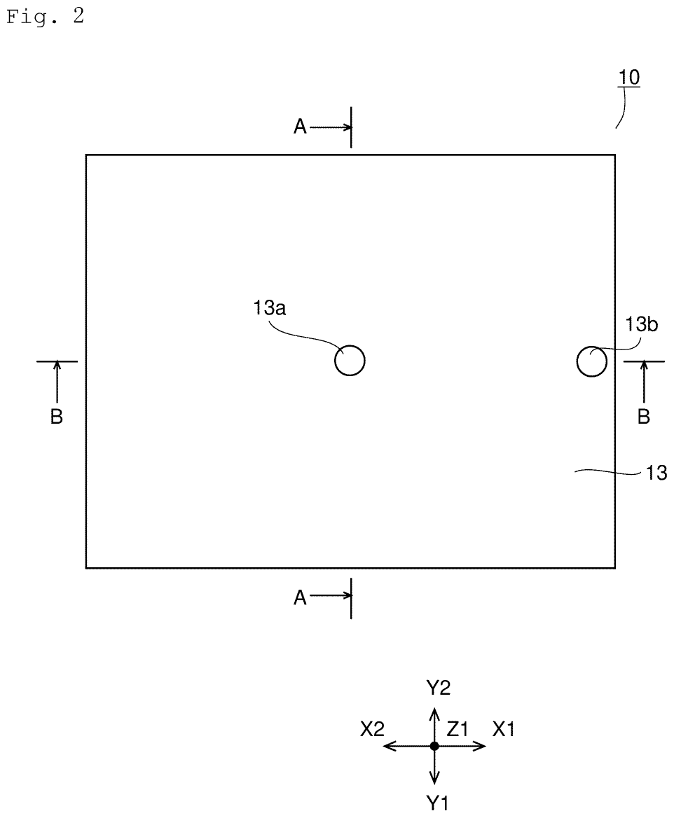

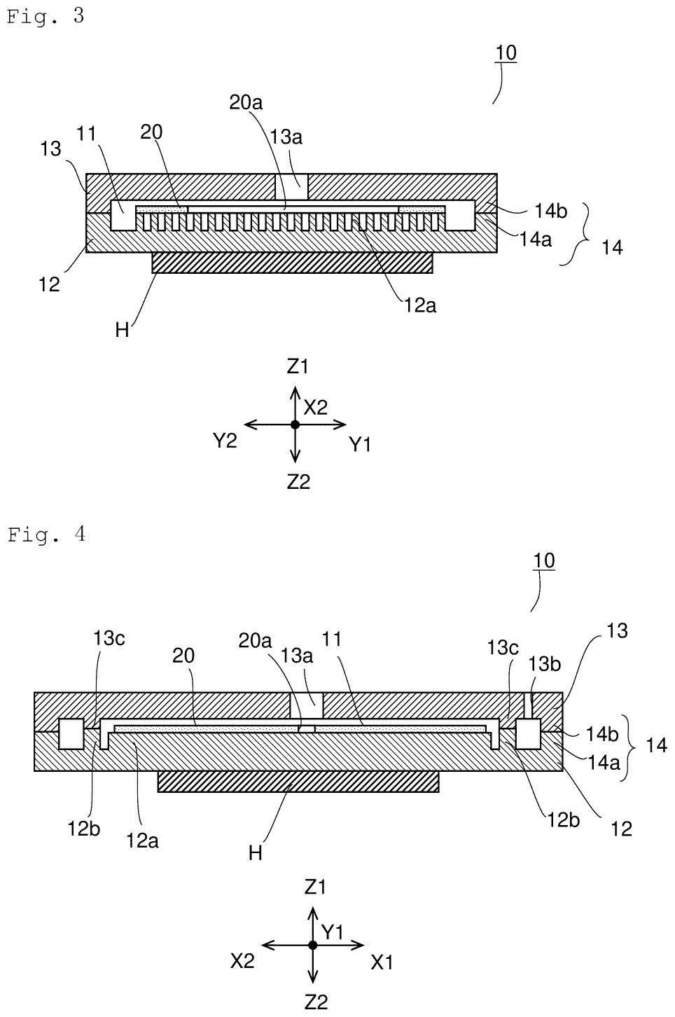

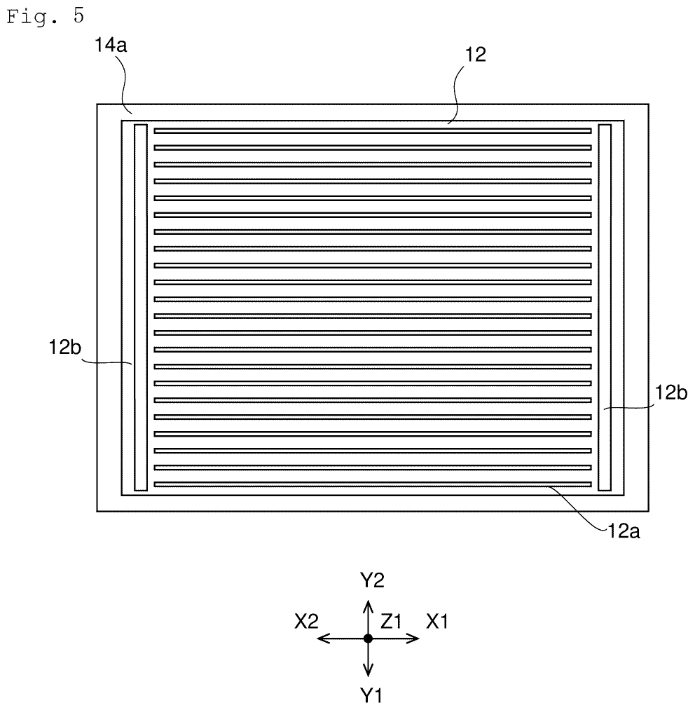

A cold plate according to an example embodiment of the present disclosure will be described. FIG. 1 is a perspective view of a cold plate 10 according to a first example embodiment of the present disclosure, and FIG. 2 is a top view of the cold plate 10. FIG. 3 is a cross-sectional view taken along line A-A in FIG. 2, and FIG. 4 is a cross-sectional view taken along line B-B in FIG. 2. FIG. 5 is a top view of a bottom wall 12 of the cold plate 10. In FIGS. 1 to 5, an elbow 15 and a refrigerant pipe 16 are omitted.

The cold plate 10 is made of metal having high thermal conductivity such as copper or aluminum, and includes the bottom wall 12, a top wall 13, a side wall 14, a blade 12a, and a cushioning portion 20. In the present example embodiment, the cold plate 10 has a rectangular shape in the top view. That is, the bottom wall 12 and the top wall 13 each have a rectangular plate shape expanding in the horizontal direction in the top view. Note that the bottom wall 12 and the top wall 13 of the present example embodiment each have a quadrangular shape in the top view, but are not limited thereto, and may have, for example, a polygonal shape having a plurality of corners in the top view or a circular shape.

The bottom wall 12 has a lower surface to be in thermal contact with a heat generating component H to be cooled, such as a CPU (see FIG. 3). The top wall 13 covers an upper surface of the bottom wall 12. The top wall 13 has a protruding portion 13c protruding from the lower surface. The protruding portion 13c is in contact with a column portion 12b described later in the vertical direction (Z1-Z2). In the present example embodiment, the protruding portion 13c extends in the arrangement direction (Y1-Y2). The protruding portion 13c and the side wall 14 face each other in the extending direction (X1-X2) and the arrangement direction (Y1-Y2) with a gap interposed therebetween. Since the protruding portion 13c is provided, the strength of the top wall 13 is further improved.

The side wall 14 is located between the bottom wall 12 and the top wall 13, and forms a refrigerant flow path 11 that surrounds the blades 12a and through which the refrigerant flows. In the present example embodiment, the side wall 14 has a rectangular annular shape in the top view. The side wall 14 connects peripheral edges of the bottom wall 12 and the top wall 13.

The side wall 14 includes a first side wall portion 14a protruding upward (Z1) from the peripheral edge of the bottom wall 12 and a second side wall portion 14b protruding downward (Z2) from the peripheral edge of the top wall 13. The upper surface of the first side wall portion 14a and the lower surface of the second side wall portion 14b are joined. In the present example embodiment, the side wall 14 is configured of the first side wall portion 14a and the second side wall portion 14b, but may be configured by only one of them. That is, the upper surface of the first side wall portion 14a may be joined to the lower surface of the top wall 13 without the second side wall portion 14b, or the lower surface of the second side wall portion 14b may be joined to the upper surface of the bottom wall 12 without the first side wall portion 14a.

The refrigerant flow path 11 is formed in an internal space surrounded by the bottom wall 12, the top wall 13, and the side wall 14. The cold plate 10 includes an inlet 13a through which the refrigerant flows into the refrigerant flow path 11 and an outlet 13b through which the refrigerant flows out of the refrigerant flow path 11.

The inlet 13a is located on one end side of the refrigerant flow path 11. The outlet 13b is located on the other end side of the refrigerant flow path 11. The refrigerant flowing into the refrigerant flow path 11 through the inlet 13a flows out of the refrigerant flow path 11 through the outlet 13b. In the present example embodiment, the inlet 13a and the outlet 13b are circular, and are formed penetrating the top wall 13 in the vertical direction. The refrigerant is liquid, and for example, an antifreeze such as an ethylene glycol aqueous solution or a propylene glycol aqueous solution, pure water, or the like is used.

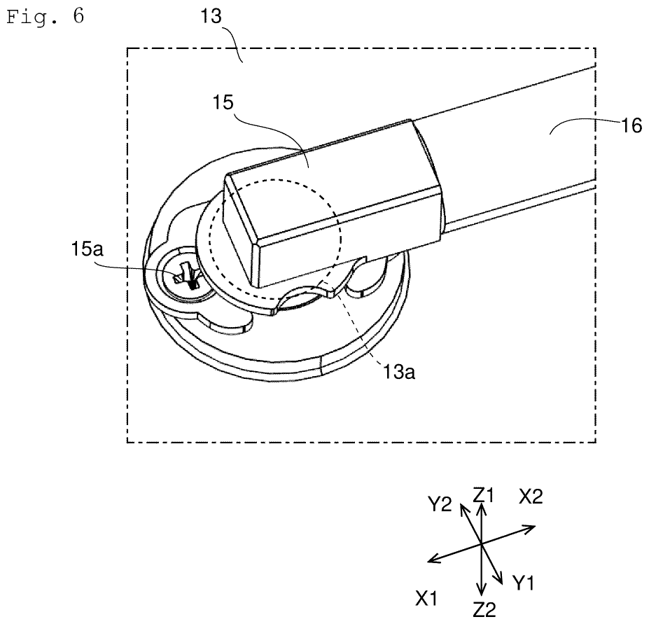

FIG. 6 is an enlarged perspective view of a part of the cold plate 10. The cold plate 10 further includes the elbow 15 made of metal and the refrigerant pipe 16. The elbow 15 is located on the upper surface of the top wall 13, and is connected to the refrigerant inlet 13a or outlet 13b of the refrigerant flow path 11. The refrigerant pipe 16 is connected to the elbow 15 in the horizontal direction by welding or brazing, and extends along the upper surface of the top wall 13.

The elbow 15 may be connected to both the inlet 13a and the outlet 13b, or may be connected to only one of them. The elbow 15 is made of a metal having high thermal conductivity such as copper or aluminum. The elbow 15 changes the circulation direction of the refrigerant from the vertical direction (Z1-Z2) to the horizontal direction. The elbow 15 is screwed to the top wall 13 via a plurality of screws 15a, for example. Although not illustrated, a seal such as a rubber O-ring or a rubber packing is preferably located between the elbow 15 and the top wall 13. As a result, refrigerant leakage around the inlet 13a and the outlet 13b can be suppressed.

Since the elbow 15 is provided, the refrigerant pipe 16 can be easily connected to the inlet 13a and the outlet 13b. In addition, the strength of the piping member around the inlet 13a and the outlet 13b can be improved. Moreover, by disposing the refrigerant pipe 16 along the upper surface of the top wall 13, the cold plate 10 can be downsized in the vertical direction (Z1-Z2). The elbow 15 is fixed to the top wall 13 by being rotated about the vertical direction (Z1-Z2), so that the extending direction of the refrigerant pipe 16 can be freely changed in the horizontal direction.

The refrigerant pipe 16 is connected to a pump (not illustrated) that circulates the refrigerant. When the pump is driven, the refrigerant circulates through the refrigerant flow path 11. The heat of the heat generating component H is transferred to the bottom wall 12 of the cold plate 10. The heat transferred to the bottom wall 12 is transferred to the refrigerant flowing through the refrigerant flow path 11. The refrigerant radiates heat via a radiator (not illustrated). As a result, a temperature rise of the heat generating component H can be suppressed.

The plurality of blades 12a is arranged side by side on the upper surface of the bottom wall 12 and linearly extend in the extending direction (X1-X2). In the present example embodiment, the blade 12a is the same member as the bottom wall 12. The blades 12a are formed by, for example, cutting a plurality of linear grooves extending in the extending direction (X1-X2) on the upper surface of the bottom wall 12. As a result, thermal conductivity from the bottom wall 12 to the refrigerant flowing through the refrigerant flow path 11 via the blades 12a is improved. The blade 12a may be formed of a member different from the bottom wall 12. For example, the blade 12a may be formed in a plate-shaped base member, and the bottom wall 12 and the base member may be welded.

The plurality of column portions 12b protrudes from the upper surface of the bottom wall 12 and face each other in the extending direction (X1-X2) of the blades 12a with the blades 12a interposed therebetween, inside the side wall 14. The upper end of the column portion 12b is positioned above (Z1) the upper end of the blade 12a. The width of the column portion 12b in the extending direction (X1-X2) and the width of the column portion 12b in the arrangement direction (Y1-Y2) are larger than the width of the blade 12a in the arrangement direction (Y1-Y2).

In the present example embodiment, the column portion 12b extends in the arrangement direction (Y1-Y2) of the blades 12a. The column portion 12b faces the blades 12a in the extending direction (X1-X2) with a gap interposed therebetween. An end of the column portion 12b in the arrangement direction (Y1-Y2) faces the side wall 14 extending in the extending direction (X1-X2) with a gap interposed therebetween in the arrangement direction (Y1-Y2) at a corner of the side wall 14. The end of the column portion 12b in the arrangement direction (Y1-Y2) faces the side wall 14 extending in the arrangement direction (Y1-Y2) with a gap interposed therebetween in the extending direction (X1-X2). The refrigerant flows through the gap around the column portion 12b.

Since the column portion 12b is provided, the strength of the bottom wall 12 is improved and bending of the bottom wall 12 can be suppressed. As a result, deformation of the blade 12a can be reduced. In addition, the column portion 12b extends in the arrangement direction (Y1-Y2) of the blades 12a, so that it is possible to further suppress bending of the bottom wall 12 in the arrangement direction (Y1-Y2).

When the top wall 13 is joined to the bottom wall 12, the column portions 12b support the top wall 13. This prevents the blade 12a from being deformed due to contact between the top wall 13 and the blade 12a. In addition, the upper end of the column portion 12b is located above (Z1) the upper end of the blade 12a, and the top wall 13 is more likely to come into contact with the column portion 12b than the blade 12a. Accordingly, it is possible to reduce contact between the top wall 13 and the blade 12a. Therefore, deformation of the blade 12a during manufacturing can be suppressed. Accordingly, it is possible to provide the cold plate 10 capable of suppressing degradation of the cooling effect due to deformation of the blade 12a. The upper end of the column portion 12b may be located at the same position as the upper end of the blade 12a.

Since the protruding portion 13c in contact with the column portion 12b is provided on the top wall 13, the strength of the top wall 13 is improved and the deflection of the top wall 13 can be suppressed. This prevents the blade 12a from being deformed due to contact between the top wall 13 and the blade 12a.

The column portions 12b are located to face each other in the extending direction (X1-X2) of the blades 12a with the blades 12a interposed therebetween, and the cutting blade is inserted in the arrangement direction (Y1-Y2) when the blades 12a are formed by cutting. As a result, the cutting blade is less likely to come into contact with the column portion 12b. Accordingly, the blades 12a aligned in the arrangement direction (Y1-Y2) can be formed with high definition, thereby improving the efficiency of manufacturing the cold plate 10.

As the cushioning portion 20, the sheet-shaped cushioning portion 20 is located between the top wall 13 and the blade 12a. The cushioning portion 20 is, for example, a mesh member in which a plurality of metal wire-shaped members are interwoven, and has a void portion (not illustrated) forming a refrigerant flow path. The cushioning portion 20 has a flow hole 20a penetrating in the vertical direction (Z1-Z2). In the present example embodiment, the flow hole 20a extends in the arrangement direction (Y1-Y2). The flow hole 20a faces the inlet 13a in the vertical direction (Z1-Z2). As a result, the refrigerant smoothly flows into the refrigerant flow path 11 via the inlet 13a and the flow hole 20a.

By disposing the cushioning portion 20, it is possible to prevent the top wall 13 and the blade 12a from coming into contact with each other and to prevent deformation of the blade 12a. In addition, the refrigerant can smoothly flow into the refrigerant flow path 11 via the inlet 13a and the flow hole 20a.

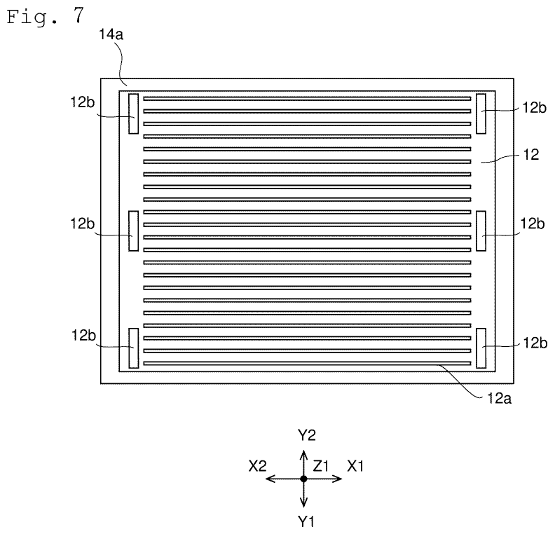

FIG. 7 is a top view illustrating a modification of the bottom wall 12 of the cold plate 10. The column portion 12b may be divided into a plurality of portions in the extending direction (X1-X2). At this time, at the corners of the side wall 14, at least some of the column portions 12b preferably face the side wall 14 extending in the extending direction (X1-X2) in the arrangement direction (Y1-Y2) with a gap interposed therebetween, and face the side wall 14 extending in the arrangement direction (Y1-Y2) in the extending direction (X1-X2) with a gap interposed therebetween. As a result, it is possible to particularly prevent the blades 12a from being deformed around the corners of the side wall 14.

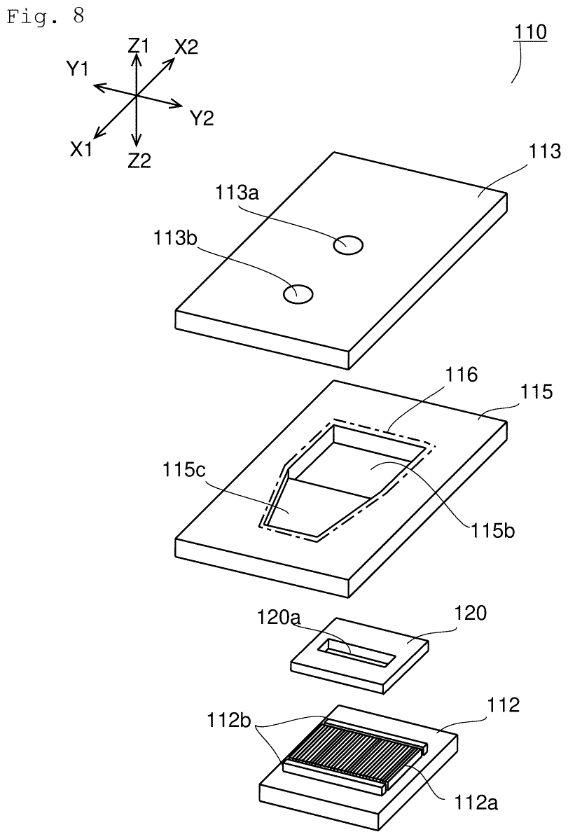

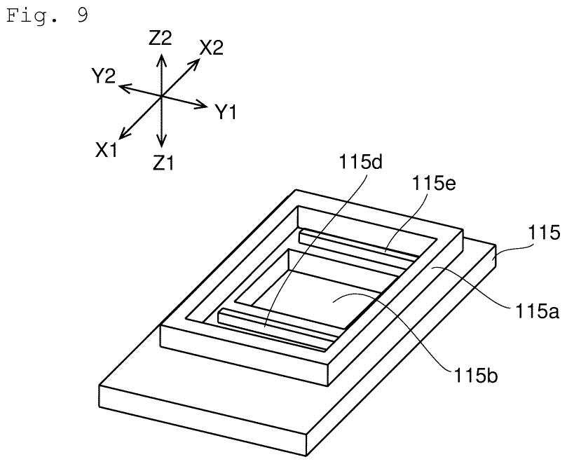

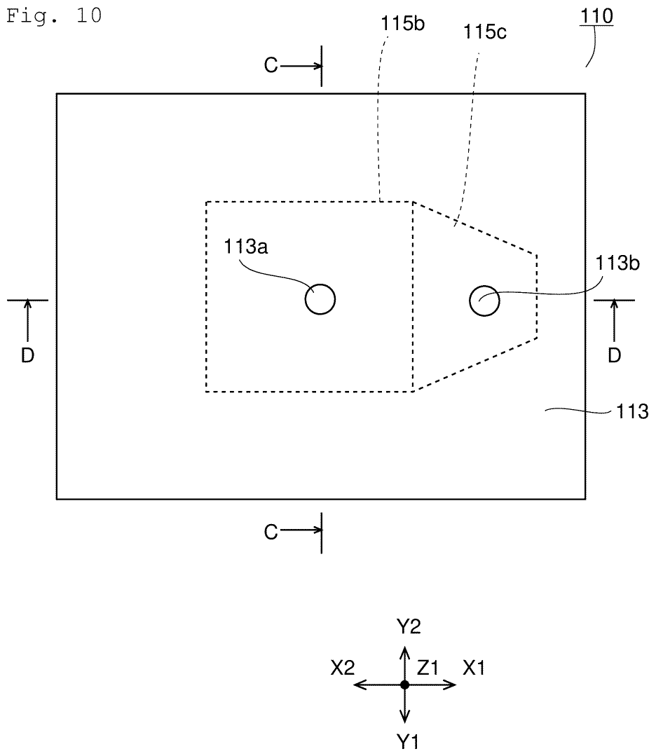

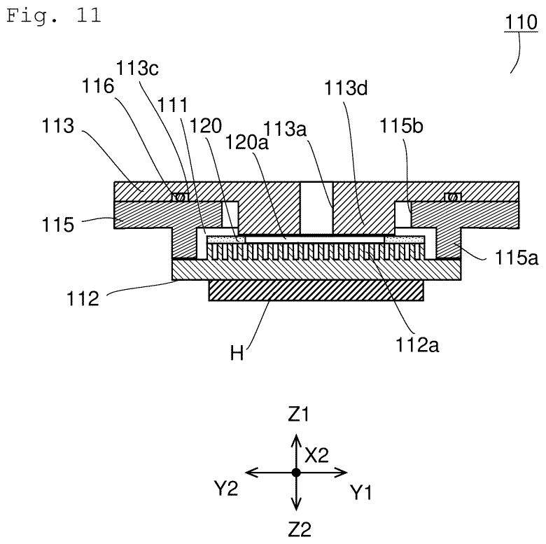

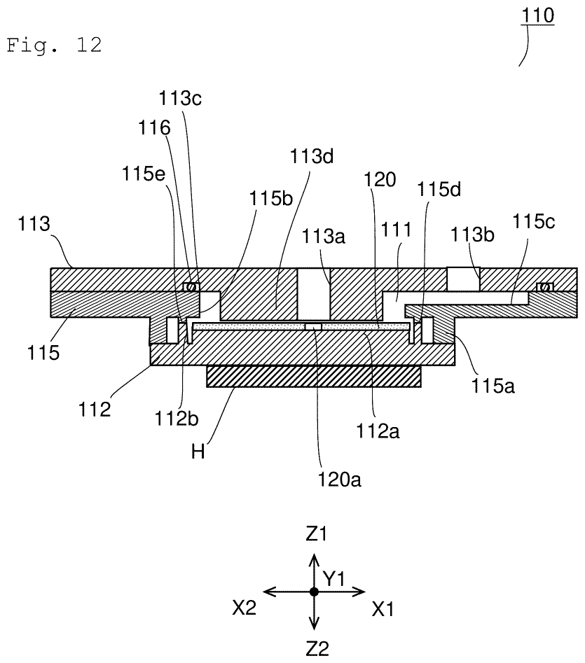

Next, a second example embodiment of the present disclosure will be described. FIG. 8 is a perspective view of a cold plate 110 according to the second example embodiment of the present disclosure. FIG. 9 is a perspective view of an intermediate lid 115, and illustrates the intermediate lid 115 from below. FIG. 10 is a top view of the cold plate 110, and FIG. 11 is a cross-sectional view taken along line C-C in FIG. 10. FIG. 12 is a cross-sectional view taken along line D-D in FIG. 10. In FIG. 8, a seal 116 is indicated by an alternate long and short dash line. In FIGS. 8 to 12, the elbow 15 and the refrigerant pipe 16 are omitted.

The cold plate 110 according to the second example embodiment further includes the intermediate lid 115 in a plate shape located between a top wall 113 and a side wall 115a. The top wall 113 and the intermediate lid 115 are in contact with each other via the annular seal 116 surrounding a through hole 115b and a recess 115c. By disposing the seal 116, the sealability inside a refrigerant flow path 111 is improved. Examples of the seal include a rubber packing.

In the present example embodiment, the side wall 115a protrudes downward (Z2) from the lower surface of the intermediate lid 115, and the lower surface is joined to the upper surface of a bottom wall 112. The side wall 115a may protrude from the upper surface of the bottom wall 112. The side wall 115a may be divided in the vertical direction (Z1-Z2) and located on the intermediate lid 115 and the bottom wall 112, respectively.

Similarly to the first example embodiment, a column portion 112b of the present example embodiment can improve the strength of the bottom wall 112 and suppress the deflection of the bottom wall 112. As a result, deformation of a blade 112a can be reduced.

Specifically, when the intermediate lid 115 is joined to the bottom wall 112, the column portion 112b supports the intermediate lid 115. This prevents the blade 112a from being deformed due to contact between the intermediate lid 115 and the blade 112a. In addition, the upper end of the column portion 112b is located above (Z1) the upper end of the blade 112a, and the intermediate lid 115 is more likely to come into contact with the column portion 112b than the blade 112a. Accordingly, it is possible to reduce contact between the intermediate lid 115 and the blade 12a. The upper end of the column portion 112b may be located at the same position as the upper end of the blade 112a.

The intermediate lid 115 includes a through hole 115b, a recess 115c, and intermediate protruding portions 115d and 115e. The through hole 115b is surrounded by the side wall 115a and penetrates in the vertical direction (Z1-Z2). In the present example embodiment, the through hole 115b has a rectangular shape in top view, but the present disclosure is not limited thereto.

The refrigerant flowing in through an inlet 113a flows into the refrigerant flow path 111 through the through hole 115b. The refrigerant flow path 111 is formed in an internal space surrounded by the bottom wall 112, the intermediate lid 115, and the side wall 115a. At this time, by providing the intermediate lid 115, the shape of the refrigerant flow path 111 can be easily designed.

The top wall 113 has a top wall protruding portion 113d which protrudes from the lower surface to the inside of the through hole 115b and through which the inlet 113a penetrates. A sheet-shaped cushioning portion 120 is located between the top wall protruding portion 113d and the blade 112a. The cushioning portion 120 has a flow hole 120a penetrating in the vertical direction (Z1-Z2). In the present example embodiment, the flow hole 120a extends in the arrangement direction (Y1-Y2).

By disposing the cushioning portion 120, it is possible to prevent the top wall protruding portion 113d and the blade 112a from coming into contact with each other and to prevent deformation of the blade 112a. In addition, the refrigerant can smoothly flow into the refrigerant flow path 111 via the inlet 113a and the flow hole 120a.

The intermediate protruding portions 115d and 115e are located inside the side wall 115a, protrude from the lower surface of the intermediate lid 115, and are in contact with the column portion 112b in the vertical direction (Z1-Z2). The intermediate protruding portions 115d and 115e are located to face each other in the extending direction (X1-X2) with the through hole 115b interposed therebetween. The intermediate protruding portion 115e is located on the opposite side (X2) of the recess 115c in the extending direction with the through hole 115b interposed therebetween.

The intermediate protruding portions 115d and 115e are located apart from the peripheral edge of the through hole 115b in the extending direction (X1-X2) (see FIG. 12). The end of the blade 112a in the extending direction (X1-X2) overlaps the peripheral edge of the through hole 115b in top view. As a result, the blade 112a can be extended in the extending direction (X1-X2) to improve the cooling effect of the cold plate 110.

The end of the blade 112a in the extending direction (X1-X2) and the peripheral edge of the through hole 115b face each other in the vertical direction (Z1-Z2) with a gap interposed therebetween. As a result, the refrigerant flowing in the extending direction (X1-X2) along the blade 112a smoothly flows through the end in the extending direction (X1) of the blade 112a toward the column portion 112b. This makes it possible to suppress an increase in flow path resistance of the refrigerant.

In the present example embodiment, the intermediate protruding portions 115d and 115e extend in the arrangement direction (Y1-Y2). The intermediate protruding portions 115d and 115e face the side wall 115a extending in the extending direction (X1-X2) in the arrangement direction (Y1-Y2) with a gap interposed therebetween. The intermediate protruding portions 115d and 115e face the side wall 115a extending in the arrangement direction (Y1-Y2) in the extending direction (X1-X2) with a gap interposed therebetween. Since the intermediate protruding portions 115d and 115e are provided, the strength of the intermediate lid 115 is improved. As a result, it is possible to further prevent the blade 112a from being deformed when the intermediate lid 115 and the bottom wall 112 are joined.

A part of the seal 116 is located between the intermediate protruding portion 115e and the peripheral edge of the through hole 115b on the upper surface of the intermediate lid 115 (see FIG. 12). As a result, the area surrounded by the seal 116 is narrowed to reduce the capacity of the refrigerant flow path 111, thereby suppressing an increase in size of the cold plate 110.

The seal 116 is located inside the groove 113c formed in the lower surface of the top wall 113. This facilitates positioning of the seal 116, thereby further improving the efficiency of manufacturing the cold plate 110.

In the present example embodiment, the recess 115c is located adjacent to the through hole 115b in the extending direction (X1), and has an upper surface recessed downward (Z2) and covered by the top wall 113. An outlet 113b of the top wall 113 is located to face the recess 115c in the vertical direction (Z1-Z2). The refrigerant flow path 111 extends from an internal space surrounded by the bottom wall 112, the intermediate lid 115, and the side wall 115a to an internal space surrounded by the recess 115c and the top wall 113.

As a result, the refrigerant flowing through the refrigerant flow path 111 surrounded by the bottom wall 112, the intermediate lid 115, and the side wall 115a flows upward (Z1) between the outer peripheral surface of the top wall protruding portion 113d and the inner peripheral surface of the through hole 115b. The refrigerant passes over the peripheral edge of the through hole 115b and flows into the recess 115c. The refrigerant flowing into the recess 115c is discharged through the outlet 113b. The cooling area can be expanded by expanding the intermediate lid 115 to provide the recess 115c. Accordingly, the heat generating component located around the heat generating component H can be cooled.

In the present example embodiment, the refrigerant flow paths 111 in the internal space surrounded by the recess 115c and the top wall 113 are narrower in the arrangement direction (Y1-Y2) than the refrigerant flow paths 111 in the internal space surrounded by the bottom wall 112, the intermediate lid 115, and the side wall 115a. More specifically, in the refrigerant flow path 111 in the internal space surrounded by the recess 115c and the top wall 113, the width in the arrangement direction (Y1-Y2) decreases as the distance from the through hole 115b increases in the extending direction (X1). As a result, the refrigerant can smoothly flow toward the outlet 113b.

The above example embodiment is merely an example of the present disclosure. The configuration of the example embodiment may be appropriately changed without departing from the technical idea of the present disclosure. In addition, the example embodiment may be implemented in combination within a feasible range. For example, in the first example embodiment, the column portion 12b is brought into contact with the protruding portion 13c in the vertical direction (Z1-Z2), but the protruding portion 13c may be omitted. At this time, the upper surface of the column portion 12b is preferably brought into contact with the lower surface of the top wall 13. In the second example embodiment, the column portion 112b is in contact with the intermediate protruding portions 115d and 115e in the vertical direction (Z1-Z2), but the intermediate protruding portions 115d and 115e may be omitted. At this time, the upper surface of the column portion 112b is preferably brought into contact with the lower surface of the intermediate lid 115.

As described above, a cold plate (10) according to one aspect of the present disclosure includes a bottom wall (12) including a lower surface to be in thermal contact with a heat generating component (H); a top wall (13) covering an upper surface of the bottom wall; blades (12a) arranged side by side on the upper surface of the bottom wall and extending linearly; and a side wall (14) located between the bottom wall and the top wall, the side wall surrounding the blades and defining a refrigerant flow path (11) through which a refrigerant flows, wherein the bottom wall includes column portions (12b) protruding from an upper surface and opposing each other in an extending direction (X1-X2) of the blades over the blades inside the side wall, and an upper end of each of the column portions is located at the same position as an upper end of each of the blades or above the upper end of each of the blades (first configuration).

In the first configuration, each of the column portions may be configured to extend in the arrangement direction (Y1-Y2) of the blades (second configuration).

In the first or second configuration, the top wall may be configured to include a protruding portion (13c) that protrudes from the lower surface and comes into contact with each of the column portions in the vertical direction (Z1-Z2) (third configuration).

In any one of the first to third configurations, the cold plate may be configured such that the side wall has a rectangular annular shape in a top view, and at least a portion of each of the column portions opposes the side wall extending in the extending direction with a gap in the arrangement direction at a corner portion of the side wall, and opposes the side wall extending in the arrangement direction with a gap in the extending direction (fourth configuration).

In any one of the first to fourth configurations, the cold plate may further include an intermediate lid (115) in a plate shape located between the top wall and the side wall, and the cold plate may be configured such that the intermediate lid includes a through hole (115b) that is surrounded by the side wall and penetrates in the vertical direction, the top wall includes an inlet (113a) through which the refrigerant flows, and the refrigerant flowing in through the inlet flows into the refrigerant flow path through the through hole (fifth configuration).

In any one of the first to fifth configurations, the cold plate may be configured such that the intermediate lid further includes an intermediate protruding portion (115d, 115e) that is located inside the side wall, protrudes from a lower surface, and is in contact with each of the column portions in a vertical direction (Z1-Z2), the intermediate protruding portion is located away from a peripheral edge of the through hole in the extending direction, the top wall and the intermediate lid are in contact with each other via a seal (116) in an annular shape surrounding the through hole, and a portion of the seal is located between the intermediate protruding portion and the peripheral edge of the through hole on an upper surface of the intermediate lid (sixth configuration).

In any one of the first to sixth configurations, the cold plate may be configured such that an end in the extending direction of each of the blades overlaps the peripheral edge of the through hole in a top view (seventh configuration).

In any one of the first to seventh configurations, the cold plate may be configured such that an end in the extending direction of each of the blades and the peripheral edge of the through hole oppose each other with a gap in the vertical direction (eighth configuration).

In any one of the first to eighth configurations, the cold plate may be configured such that the top wall includes a top wall protruding portion (113d) that protrudes from the lower surface to the inside of the through hole and through which the inlet passes, and a sheet-shaped cushioning portion (120) is located between the top wall protruding portion and the blades (ninth configuration).

In any one of the first to ninth configurations, the cold plate may be configured such that the intermediate lid includes a recess (115c) located adjacent to the through hole in the extending direction and including an upper surface recessed downward and covered with the top wall, the top wall includes an outlet (113b) that is located to face the recess in the vertical direction and through which the refrigerant flows out, the refrigerant flow path extends from an internal space surrounded by the bottom wall, the intermediate lid, and the side wall to an internal space surrounded by the recess and the top wall, the seal surrounds the through hole and the recess, and a part of the seal is located between the intermediate protruding portion located on a side opposite to the recess over the through hole in the extending direction and the peripheral edge of the through hole (tenth configuration).

In any one of the first to tenth configurations, the cold plate may be configured such that the refrigerant flow path in the internal space surrounded by the recess and the top wall is narrower in the arrangement direction than the refrigerant flow path in the internal space surrounded by the bottom wall, the intermediate lid, and the side wall (eleventh configuration).

In any one of the first to eleventh configurations, the cold plate may be configured such that the refrigerant flow path in the internal space surrounded by the recess and the top wall becomes narrower in the arrangement direction as a distance from the through hole increases in the extending direction (twelfth configuration).

In any one of the first to twelfth configurations, the cold plate may be configured to further include an elbow (15) made of metal that is located on an upper surface of the top wall and is connected to an inlet (13a) or an outlet (13b) of the refrigerant in the refrigerant flow path, and a refrigerant pipe (16) connected to the elbow by welding or brazing and extending along an upper surface of the top wall (thirteenth configuration).

Features of the above-described example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A cold plate comprising:
a bottom wall including a lower surface to be in thermal contact with a heat generating component;
a top wall covering an upper surface of the bottom wall;
blades arranged side by side on the upper surface of the bottom wall and extending linearly; and
a side wall located between the bottom wall and the top wall, the side wall surrounding the blades and defining a refrigerant flow path through which a refrigerant flows; wherein
the bottom wall includes column portions protruding from an upper surface and opposing each other in an extending direction of the blades over the blades inside the side wall; and
an upper end of each of the column portions is located at a same position as an upper end of each of the blades or above the upper end of each of the blades.

2. The cold plate according to claim 1, wherein each of the column portions extends in an arrangement direction of the blades.

3. The cold plate according to claim 1, wherein the top wall includes a protruding portion that protrudes from a lower surface and is in contact with each of the column portions in a vertical direction.

4. The cold plate according to claim 3, wherein
the side wall has a rectangular annular shape in a top view; and
at least a portion of each of the column portions opposes the side wall extending in the extending direction with a gap in an arrangement direction at a corner portion of the side wall, and opposes the side wall extending in the arrangement direction with a gap in the extending direction.

5. The cold plate according to claim 1, further comprising:
an intermediate lid in a plate shape located between the top wall and the side wall; wherein
the intermediate lid includes a through hole that is surrounded by the side wall and penetrates in the vertical direction;
the top wall includes an inlet through which the refrigerant flows; and
the refrigerant flowing in through the inlet flows into the refrigerant flow path through the through hole.

6. The cold plate according to claim 5, wherein
the intermediate lid further includes an intermediate protruding portion that is located inside the side wall, protrudes from a lower surface, and is in contact with each of the column portions in a vertical direction;
the intermediate protruding portion is spaced away from a peripheral edge of the through hole in the extending direction;
the top wall and the intermediate lid are in contact with each other via a seal in an annular shape surrounding the through hole; and
a portion of the seal is located between the intermediate protruding portion and the peripheral edge of the through hole on an upper surface of the intermediate lid.

7. The cold plate according to claim 6, wherein an end of each of the blades in the extending direction overlaps the peripheral edge of the through hole in a top view.

8. The cold plate according to claim 7, wherein an end of each of the blades in the extending direction and the peripheral edge of the through hole oppose each other with a gap in the vertical direction.

9. The cold plate according to claim 5, wherein
the top wall includes a top wall protruding portion which projects from a lower surface to an inside of the through hole and through which the inlet penetrates; and
a sheet-shaped cushioning portion is located between the top wall protruding portion and the blades.

10. The cold plate according to claim 6, wherein
the intermediate lid includes a recess located adjacent to the through hole in the extending direction and including an upper surface recessed downward and covered with the top wall;
the top wall includes an outlet that is located to oppose the recess in a vertical direction and through which the refrigerant flows out;
the refrigerant flow path extends from an internal space surrounded by the bottom wall, the intermediate lid, and the side wall to an internal space surrounded by the recess and the top wall;
the seal surrounds the through hole and the recess; and
a portion of the seal is located between the intermediate protruding portion located on a side opposite to the recess over the through hole in the extending direction and the peripheral edge of the through hole.

11. The cold plate according to claim 10, wherein the refrigerant flow path in the internal space surrounded by the recess and the top wall is narrower in an arrangement direction than the refrigerant flow path in the internal space surrounded by the bottom wall, the intermediate lid, and the side wall.

12. The cold plate according to claim 11, wherein the refrigerant flow path in the internal space surrounded by the recess and the top wall becomes narrower in the arrangement direction as a distance from the through hole increases in the extending direction.

13. The cold plate according to claim 1, further comprising:
an elbow made of metal that is located on an upper surface of the top wall and is connected to an inlet or an outlet of the refrigerant in the refrigerant flow path; and
a refrigerant pipe connected to the elbow and extends along an upper surface of the top wall.
